(19) United States
(12) Patent Application Publication
(10) Pub. No.: US 2024/0234370 A1
(43) Pub. Date: Jul. 11, 2024

(54) SEMICONDUCTOR DEVICE AND RELATED FABRICATION METHOD

(71) Applicant: Wolfspeed, Inc., Durham, NC (US)

(72) Inventor: Shadi Sabri, Apex, NC (US)

(21) Appl. No.: 18/152,130

(22) Filed: Jan. 9, 2023

(51) Int. Cl. H01L 25/065; H01L 21/02; H01L 21/311; H01L 21/3205; H01L 21/3213; H01L 21/77; H01L 23/14; H01L 23/16; H01L 23/31

(52) U.S. Cl. CPC H01L 25/0655; H01L 21/0214; H01L 21/02164; H01L 21/0226; H01L 21/31116; H01L 21/32051; H01L 21/32135; H01L 21/77; H01L 23/147; H01L 23/16; H01L 23/3107

(57) ABSTRACT

A semiconductor device and related fabrication method are disclosed. Specifically, a multi-layer structure in the semiconductor device is formed on a surface of a substrate and surrounded by a dicing street(s). The multi-layer structure can be formed to include an inter-layer dielectric (ILD) layer to act as an etch stop. A spacer dielectric layer is then deposited over the multi-layer structure and the surrounding dicing street(s). The spacer dielectric layer is then etched back to reveal the surrounding dicing street(s) while leaving in place a sidewall between multi-layer structure and the surrounding dicing street(s). By using the ILD layer to provide the etch stop, in conjunction with depositing the spacer dielectric layer before etching and leaving in place the sidewall after etching, it is possible to protect the multi-level structure for uncompromised integrity and performance.

### FIELD OF THE DISCLOSURE

The technology of the disclosure relates generally to a semiconductor device and a method for fabricating the semiconductor device.

### BACKGROUND

Semiconductor devices, such as transistors and diodes, can be found in almost all electronic devices. Fabrication of these devices often takes numerous meticulous processing steps, such as deposition, photoresist coating, lithography, etching, ionization, and packaging). Etching, for example, is a process to remove a processing material to reveal a three-dimensional (3D) pattern of open areas over a semiconductor die. The etching step must be precise and not impact the overall integrity and stability of the overall semiconductor device.

Typically, semiconductor dies are formed on a piece of wafer during fabrication. FIG. 1A is a schematic diagram of an exemplary top view of multiple dies 10 formed on a wafer 12. As illustrated in FIG. 1A, each of the dies 10 is surrounded by multiple dicing streets 14, which are cut-away areas on the wafer 12 for separating the dies 10 from one another.

FIG. 1B is a schematic diagram providing an exemplary side view of one of the dies 10 in FIG. 1A along a cutoff line 18. Common elements between FIGS. 1A and 1B are shown therein with common element numbers and will not be re-described herein.

Herein, the die 10 is formed on a surface 18 of the wafer 12 and sealed to the respective edge 16 of the surrounding dicing street 14 to protect one or more inner layers 20 in the die 10. In a non-limiting example, the dicing streets 14 can be covered by a metal layer (ML) during fabrication. As such, a dry ML etch is typically performed on the dicing street 14 to remove the metal layer and reveal the dicing street 14. Notably, the ML etch may be physical in nature and have a significant etch rate. As a result, the ML etch may create a recess 22 (e.g., 100-500 nanometers) below the surface 18. As such, portions of the wafer 12 may be inadvertently exposed and etched, which can lead to reliability issues in the die 10. Hence, it is desirable to avoid, or at least reduce the extent of, the recess 22 during fabrication of the die 10.

### SUMMARY

Aspects disclosed in the detailed description include a semiconductor device and related fabrication method. Specifically, a multi-layer structure in the semiconductor device is formed on a surface of a substrate and surrounded by a dicing street(s). The multi-layer structure can be formed to include an inter-layer dielectric (ILD) layer to act as an etch stop. A spacer dielectric layer is then deposited over the multi-layer structure and the surrounding dicing street(s). The spacer dielectric layer is then etched back to reveal the surrounding dicing street(s) while leaving in place a sidewall between the multi-layer structure and the surrounding dicing street(s). By using the ILD layer to provide the etch stop, in conjunction with depositing the spacer dielectric layer before etching and leaving in place the sidewall after etching, it is possible to protect the multi-level structure for uncompromised integrity and performance.

In one aspect, a semiconductor device is provided. The semiconductor device includes a substrate having a surface. The semiconductor device also includes a multi-layer structure provided on the surface. The semiconductor device also includes a spacer dielectric layer provided over the multi-layer structure and on the surface to form a sidewall.

In another aspect, a semiconductor device is provided. The semiconductor device includes a substrate having a surface. The semiconductor device also includes a multi-layer structure provided on the surface. The semiconductor device also includes a spacer dielectric layer consisting of a selected dielectric material and provided over the multi-layer structure and on the surface to form a sidewall up to an outer edge of the sidewall.

In another aspect, a semiconductor device is provided. The semiconductor device includes a substrate having a surface. The semiconductor device also includes a multi-layer structure provided on the surface. The semiconductor device also includes a spacer dielectric layer provided over the multi-layer structure to form a sidewall on an inherent outer edge of the multi- layer structure.

In another aspect, a semiconductor device is provided. The semiconductor device includes a substrate having a surface. The semiconductor device also includes a multi-layer structure provided on the surface. The semiconductor device also includes a spacer dielectric layer provided over the multi-layer structure and on the surface to form a sidewall. The sidewall includes an inner edge that coincides with an inherent outer edge of the multi-layer structure. The sidewall also includes an outer edge that extends the inherent outer edge of the multi-layer structure to form an expanded outer edge of the multi-layer structure.

In another aspect, a method for fabricating a semiconductor device is provided. The method includes depositing an inter-layer dielectric (ILD) metal layer (ML) on a surface of a substrate, a multi-layer structure. The multi-layer structure includes an ILD layer acting as an etch stop during an ML etch and/or a final passivation etch. The method also includes depositing a spacer dielectric layer over the multi-layer structure to form a sidewall on an inherent outer edge of the multi-layer structure and extend the inherent outer edge of the multi-layer structure to an extended outer edge of the multi-layer structure.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1A is a schematic diagram of an exemplary top view of multiple dies formed on a wafer;

FIG. 1B is a schematic diagram providing an exemplary side view of one of the dies in FIG. 1A;

FIG. 2 is a schematic diagram of an exemplary side view of a semiconductor device fabricated based on embodiments of the present disclosure to protect a multi-layer structure in the semiconductor device and prevent over etch to a dicing street surrounding the semiconductor device;

FIG. 3 is a flowchart of an exemplary process for fabricating the semiconductor device of FIG. 2;

FIGS. 4A-4H are schematic diagrams providing exemplary illustrations of each processing step involved in the process of FIG. 3; and

FIG. 5 is a schematic diagram of an exemplary side view of a semiconductor device fabricated based on embodiments of the present disclosure to protect a multi-layer structure in the semiconductor device and prevent over etch to a dicing street surrounding the semiconductor device according to a second embodiment.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re- described.

Aspects disclosed in the detailed description include a semiconductor device and related fabrication method. Specifically, a multi-layer structure in the semiconductor device is formed on a surface of a substrate and surrounded by a dicing street(s). The multi-layer structure can be formed to include an inter-layer dialect (ILD) layer to act as an etch stop. A spacer dielectric layer is then deposited over the multi-layer structure and the surrounding dicing street(s). The spacer dielectric layer is then etched back to reveal the surrounding dicing street(s) while leaving in place a sidewall between multi-layer structure and the surrounding dicing street(s). By using the ILD layer to provide the etch stop, in conjunction with depositing the spacer dielectric layer before etching and leaving in place the sidewall after etching, it is possible to protect the multi-level structure for uncompromised integrity and performance.

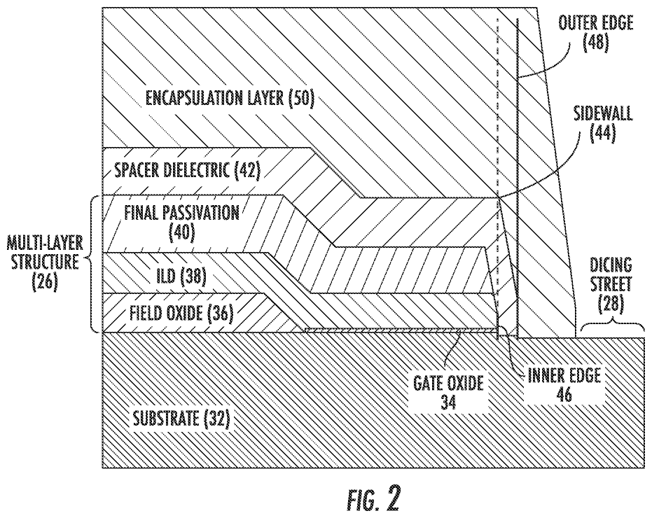

FIG. 2 is a schematic diagram of an exemplary side view of a semiconductor device 24 fabricated according to embodiments of the present disclosure to protect a multi-layer structure 26 in the semiconductor device 24 and prevent over etch to a dicing street 28 surrounding the semiconductor device 24. Herein, the multi-layer structure 26 is provided on a surface 30 (e.g., a planar surface) of a substrate 32 (e.g., a semiconductor wafer). The substrate 32 may be a bulk growth silicon carbide (SiC) and/or a SiC epitaxial layer. Since the dicing street 28 is part of the surface 30 of the substrate 32, the dicing street 28 can be said to occupy a portion of the surface 30. In a non-limiting example, the multi-layer structure 26 includes a gate oxide layer 34, a field oxide layer 36, an inter-layer dielectric (ILD) layer 38, and a final passivation layer 40.

In an embodiment, the gate oxide layer 34 and the field oxide layer 36 are both grown or deposited on the surface 30 and adjacent to each other. The ILD layer 38, which can be silicon dioxide (SiO2), silicon nitride (SiN), or a combination thereof as an example, is deposited over the gate oxide layer 34 and the field oxide layer 36. The final passivation layer 40 is deposited over the ILD layer 38.

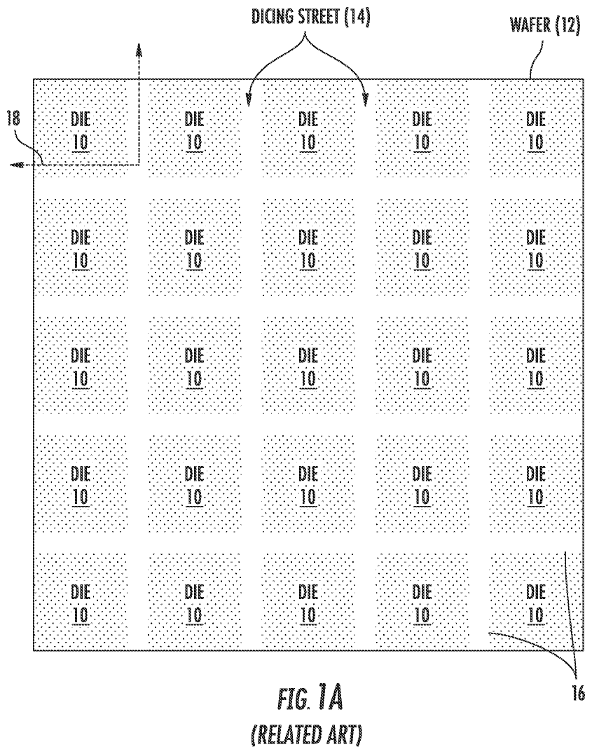

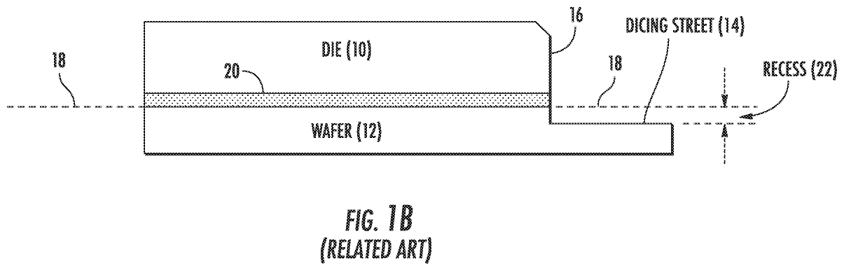

The semiconductor device 24 also includes a spacer dielectric layer 42 that is deposited over the multi-layer structure 26 and the dicing street 28. In one aspect, the spacer dielectric layer 42 may include one or more types of dielectric material, such as SiN, silicon dioxide (SiO₂), silicon (Si), silicon oxynitride (SiON), a SiN liner with an oxide spacer, a SiN liner with an SiON spacer, and so on. The spacer dielectric layer etch can have a substantially lower silicon carbide (SiC) etch rate compared to the metal layer (ML) etch, thus making it possible to reduce the chance of over etch on the dicing street 28. As a result, it is possible to reduce the recess 22 in FIG. 1B during, for example, a dry etch process.

In another aspect, the spacer dielectric layer 42 can create a sidewall 44 (a.k.a. protective sidewall) to completely seal the multi-layer structure 26. For example, the sidewall 44 may be formed with an inner edge 46 encompassing the multi-layer structure 26 and an outer edge 48 touching the dicing street 28. The inner edge 46 of the sidewall 44 coincides with an inherent outer edge of the multi-layer structure 26, and the outer edge 48 of the sidewall 44 extends the inherent outer edge of the multi-layer structure 26 to form an expanded outer edge of the multi-layer structure 26. In other words, the inner edge 46 of the sidewall is the same as an original outer edge of the multi-layer structure 26 and the outer edge 48 of the sidewall 44 defines a new outer edge of the multi-layer structure 26. The inner edge 46 and the outer edge 48 collectively define a thickness d_{sw}(d_{sw}>0) of the sidewall 44. By depositing the spacer dielectric layer 42 before etching and creating the sidewall 44 after etching, it is possible to protect the multi-layer structure 26 for uncompromised integrity and performance.

After performing a spacer etch process (e.g., dry etch) on the spacer dielectric layer 42 to create the sidewall 44 and reveal the dicing street 28, an encapsulation layer 50 (e.g., polyimide) can be deposited over the spacer dielectric layer 42. As illustrated in FIG. 2, the encapsulation layer 50 not only completely encapsulates the outer edge 48 of the sidewall 44, but also covers a portion (but not all) of the dicing street 28 on the surface 30.

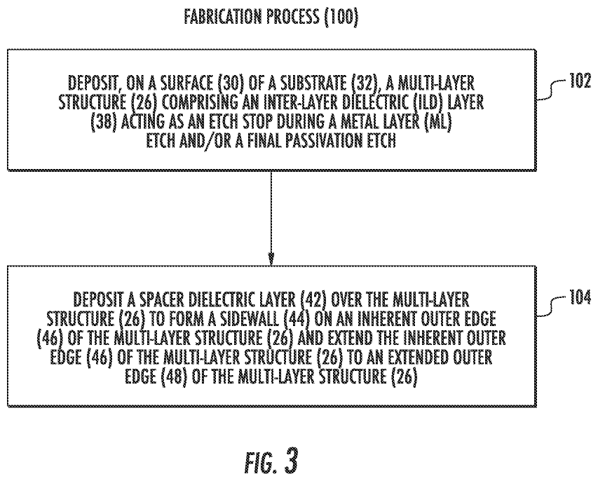

The semiconductor device 24 can be fabricated based on a process. In this regard, FIG. 3 is a flow diagram of an exemplary process 100 for fabricating the semiconductor device 24 of FIG. 2. Elements in FIG. 2 are referenced in the process 100 and will not be re-described herein.

According to the process 100, the multi-layer structure 26 is first deposited on the surface 30 of the substrate 32 (step 102). Notably, the multi- layer structure 26 includes the ILD layer 38 that can provide an etch stop during an OM etch and/or a final passivation etch.

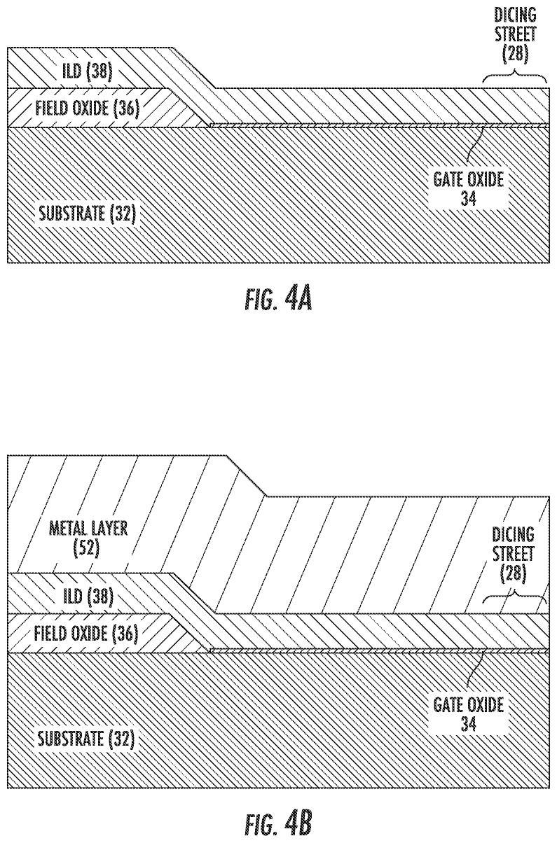

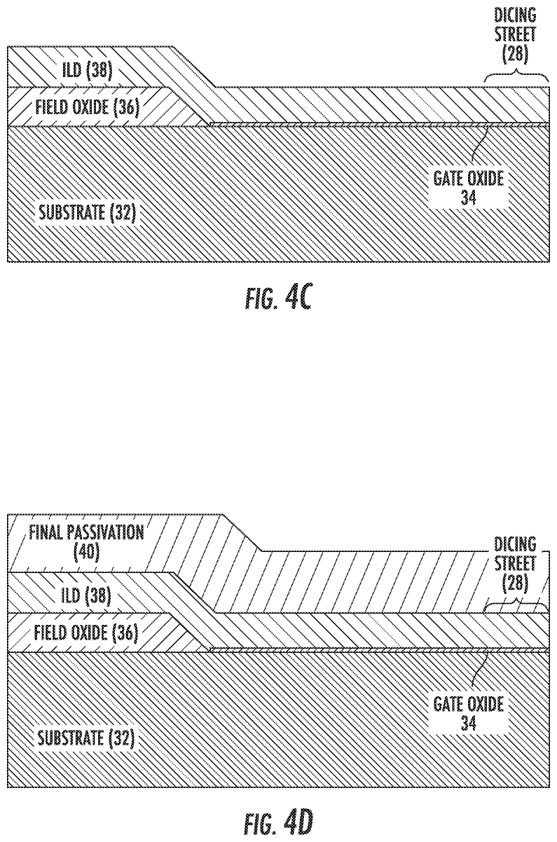

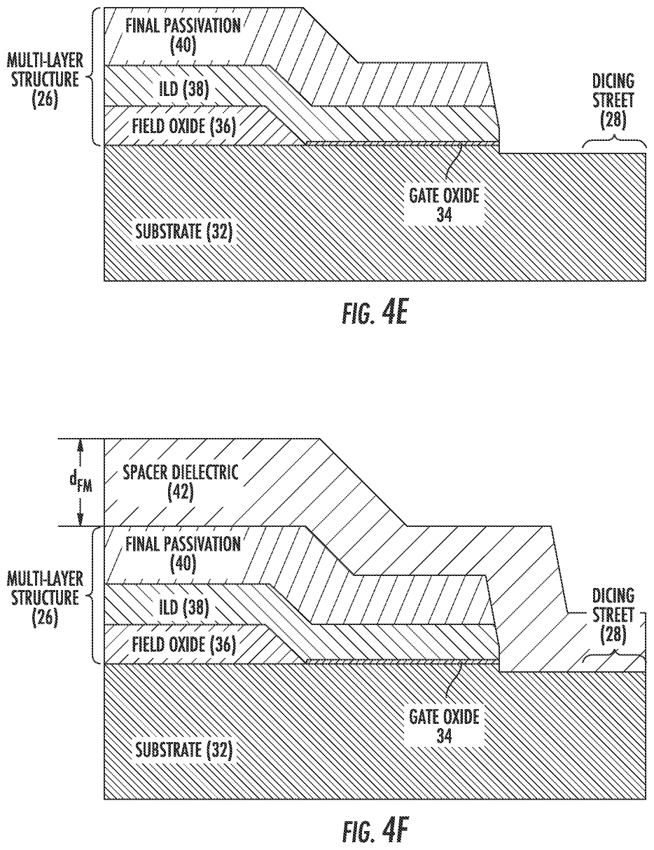

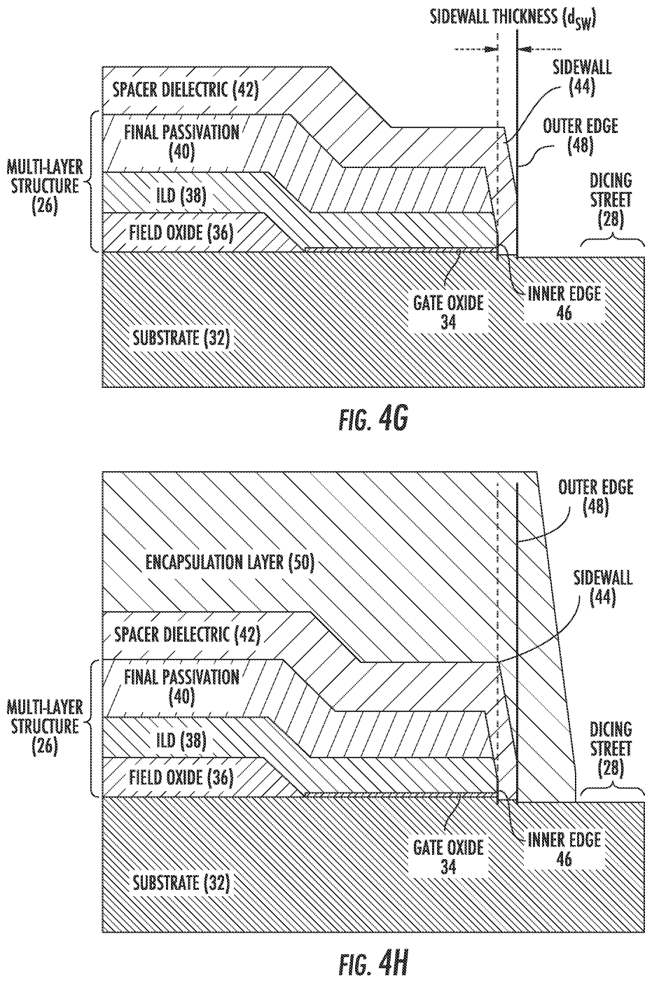

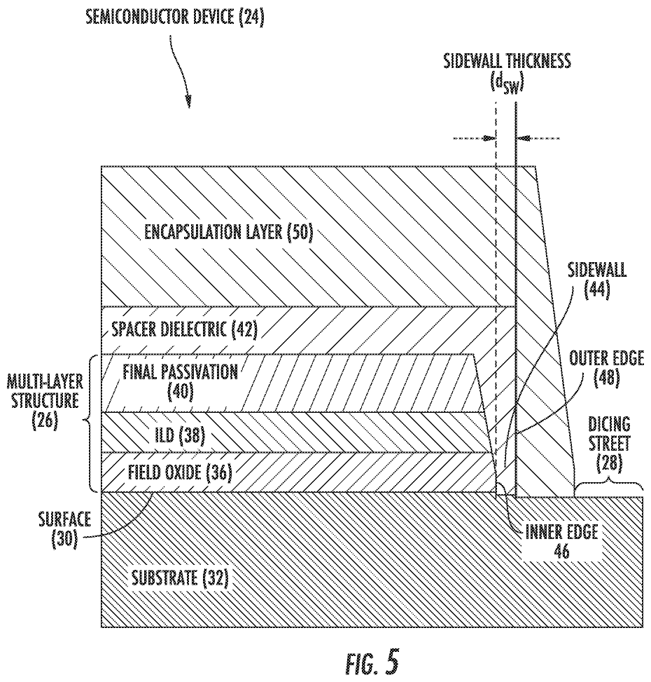

The step of depositing the multi-layer structure 26 are further illustrated in FIGS. 4A-4E. First, the field oxide layer 36 and the gate oxide layer 34 are first provided on the surface 30 of the substrate 32.

Next in the process 100 and as illustrated in FIG. 4A, the ILD layer 38 is deposited over the field oxide layer 36 and the gate oxide layer 34.

Next in the process 100 and as illustrated in FIG. 4B, an ML 52 is deposited over the ILD layer 38 during metal deposition.

Next in the process 100 and as illustrated in FIG. 4C, the ML etch (e.g., dry etch) is performed to remove the ML 52 and reveal the dicing street 28. Given that the ILD layer 38 was deposited before the ML etch to cover the entire dicing street 28, the ILD layer 38 will act as the etch stop during the ML etch. As a result, it is possible to substantially reduce the recess 22 in FIG. 1B by preventing over etch on the dicing street 28.

Next in the process 100 and as illustrated in FIG. 4D, the final passivation layer 40 is deposited on the substrate 32. Notably, the final passivation layer 40 completely covers the ILD layer 38 and the dicing street 28.

Next in the process 100 and as illustrated in FIG. 4E, the final passivation etch is performed to expose the portion of the surface occupied by the dicing street 28. The remaining of the ILD layer 38 after the ML etch may also act as the etch stop during the final passivation etch. Herein, the final passivation etch not only clears bond pads, but also reveals the dicing street 28 by removing the final passivation layer 40 and the ILD layer 38 that were previously deposited over the dicing street 28. The remaining gate oxide layer 34, the field oxide layer 36, the ILD layer 38, and the final passivation layer 40 collectively form the multi-layer structure 26. Notably, the field oxide layer 36, the

ILD layer 38, and the final passivation layer 40 are all terminated at the inherent outer edge 46 of the multi-layer structure 26.

After depositing the multi-layer structure 26, the spacer dielectric layer 42 is deposited over the multi-layer structure 26 to form the sidewall 44 on the inherent outer edge 46 of the multi-layer structure 26 and extend the inherent outer edge 46 of the multi-layer structure 26 to the extended outer edge 48 of the multi-layer structure 26 (step 104). The step of depositing the spacer dielectric layer 42 are further illustrated in FIGS. 4F-4H.

Next in the process 100 and as illustrated in FIG. 4F, the spacer dielectric layer 42 is deposited over the final passivation layer 40 and the portion of the surface 30 occupied by the dicing street 28. The spacer dielectric layer 42 is deposited with a respective film thickness d that is proportionally related to the thickness d of the sidewall. In a non-limiting example, the film thickness d can be between one-half (½) and five times (5×) the thickness d_{sw} (0.5 d_{sw}≤d_{FM}≤5 d_{SW}).

Next in the process 100 and as illustrated in FIG. 4G, a spacer etch is performed to etch back the spacer dielectric layer 42 to form the sidewall 44 at the inherent outer edge 48 of the multi-layer structure 26 and reveal a portion of the surface 30 occupied by the dicing street 28 beyond the extended outer edge 48 of the multi-layer structure 26. Inside the sidewall 44, each of the gate oxide layer 34, the ILD layer 38, and the final passivation layer 40 is terminated at the inner edge 46 of the sidewall 44. Outside the sidewall 44, the dicing street 28 touches the outer edge 48 of the sidewall 44. Although the etch performed on the spacer dielectric layer 42 may result in a minor recess compared to the recess 22 in FIG. 1B, the thickness d of the sidewall 44 may nevertheless completely seal the multi-layer structure 26 from any recess on the dicing street 28. In certain embodiments, the resultant recess may be less than 50 nanometers, less than 25 nanometers, or even less than 15 nanometers, which is a significant improvement over the 100 to 500 nanometer deep (or more) recesses of the related art.

Next in the process 100 and as illustrated in FIG. 4H, the encapsulation layer 50 is deposited to completely encapsulate (a.k.a. seal) the outer edge 48 of the sidewall 44, which ultimately seals the multi-layer structure 26.

With reference to FIG. 5, an alternate embodiment is shown. In this embodiment, the gate oxide 34 provided in FIG. 2 is removed. As such, the field oxide 36 extends all the way to the inner edge 46. The ILD layer 38 resides over the filed oxide 36 and also extends to the inner edge 46. The final passivation layer 40 resides over the ILD layer 38. The spacer dielectric layer 42 resides over the final passivation layer 40 and down the sides of the final passivation layer 40, the ILD layer 38, and the field oxide layer 36 to the substrate 32. The outer side of the spacer dielectric layer 42 defines the outer edge 48 and provides the sidewall 44.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A semiconductor device comprising:
a substrate having a surface;
a multi-layer structure provided on the surface; and
a spacer dielectric layer provided over the multi-layer structure and on the surface to form a sidewall.

2. The semiconductor device of claim 1, wherein the spacer dielectric layer comprises at least one of: silicon nitride (SiN), silicon dioxide (SiO₂), silicon (Si), silicon oxynitride (SiON), a SiN liner with an oxide spacer, and a SiN liner with an SiON spacer.

3. The semiconductor device of claim 1, wherein the substrate comprises at least one of a bulk growth silicon carbide (SiC) and a SiC epitaxial layer.

4. The semiconductor device of claim 1, wherein the multi-layer structure comprises:
a gate oxide layer provided on the surface;
a field oxide layer provided on the surface and adjacent to the gate oxide layer;
an inter-layer dielectric (ILD) layer provided over the gate oxide layer and the field oxide layer; and
a final passivation layer provided over the ILD layer;
wherein each of the gate oxide layer, the ILD layer, and the final passivation layer is terminated at an inner edge of the sidewall.

5. The semiconductor device of claim 1, wherein the sidewall comprises:
an inner edge that coincides with an inherent outer edge of the multi-layer structure; and
an outer edge that extends the inherent outer edge of the multi-layer structure to form an expanded outer edge of the multi-layer structure.

6. The semiconductor device of claim 5, further comprising an encapsulation layer provided over the spacer dielectric layer and a portion of a dicing street surrounding the outer edge of the sidewall.

7. A semiconductor device comprising:
a substrate having a surface;
a multi-layer structure provided on the surface; and
a spacer dielectric layer comprising a selected dielectric material and provided over the multi-layer structure and on the surface to form a sidewall around the multi-layer structure to thereby seal the multi- layer structure completely up to an outer edge of the sidewall.

8. The semiconductor device of claim 7, wherein the selected dielectric material is at least one of: silicon nitride (SiN), silicon dioxide (SiO₂), silicon (Si), silicon oxynitride (SiON), a SiN liner with an oxide spacer, and a SiN liner with an SiON spacer.

9. The semiconductor device of claim 7, wherein the substrate comprises at least one of a bulk growth silicon carbide (SiC) and a SiC epitaxial layer.

10. The semiconductor device of claim 7, wherein the multi-layer structure comprises:
a gate oxide layer provided on the surface;
a field oxide layer provided on the surface and adjacent to the gate oxide layer;
an inter-layer dielectric (ILD) layer provided over the gate oxide layer and the field oxide layer; and
a final passivation layer provided over the ILD layer;
wherein each of the gate oxide layer, the ILD layer, and the final passivation layer is terminated at an inner edge of the sidewall.

11. The semiconductor device of claim 7, further comprising an encapsulation layer provided over the spacer dielectric layer and a portion of a dicing street surrounding the outer edge of the sidewall.

12. A semiconductor device comprising:
a substrate having a surface;
a multi-layer structure provided on the surface; and
a spacer dielectric layer provided over the multi-layer structure to form a sidewall on an inherent outer edge of the multi-layer structure.

13. The semiconductor device of claim 12, wherein the substrate comprises at least one of a bulk growth silicon carbide (SiC) and a SiC epitaxial layer.

14. The semiconductor device of claim 12, wherein the multi-layer structure comprises:
a gate oxide layer provided on the surface;
a field oxide layer provided on the surface and adjacent to the gate oxide layer;
an inter-layer dielectric (ILD) layer provided over the gate oxide layer and the field oxide layer; and
a final passivation layer provided over the ILD layer;
wherein each of the gate oxide layer, the ILD layer, and the final passivation layer is terminated at an inner edge of the sidewall.

15. A semiconductor device comprising:
a substrate having a surface;
a multi-layer structure provided on the surface; and
a spacer dielectric layer provided over the multi-layer structure to form a sidewall, wherein the sidewall comprises:
an inner edge that coincides with an inherent outer edge of the multi-layer structure; and
an outer edge that extends the inherent outer edge of the multi- layer structure to an expanded outer edge of the multi-layer structure.

16. A method for fabricating a semiconductor device comprising:
providing, on a surface of a substrate, a multi-layer structure comprising an inter-layer dielectric (ILD) layer;
creating an etch stop layer by removing a portion of the ILD layer, wherein the etch stop layer is a remaining portion of the ILD layer;
providing a final passivation layer on the multi-layer structure and etch stop layer; and
removing a portion of the final passivation layer and the etch stop layer to create access to the substrate.

17. The method of claim 16, wherein providing the multi-layer structure comprises:
depositing a field oxide layer and a gate oxide layer on the surface of the substrate;
depositing the ILD layer over the field oxide layer and the gate oxide layer;
depositing a metal layer (ML) over the ILD layer;
performing an ML etch to remove the ML with the ILD layer providing an etch stop to protect a portion of the surface from over etch;
depositing the final passivation layer over the ILD layer; and
performing a final passivation etch to expose the portion of the surface.

18. The method of claim 16 further comprising depositing a spacer dielectric layer over the multi-layer structure to form a sidewall on an inherent outer edge of the multi-layer structure and extend the inherent outer edge of the multi-layer structure to an extended outer edge of the multi-layer structure.

19. The method of claim 18, wherein depositing the spacer dielectric layer comprises:
depositing the spacer dielectric layer over the final passivation layer and a portion of the surface of the substrate;
performing a spacer etch to etch back the spacer dielectric layer to thereby form a sidewall at the inherent outer edge of the multi-layer structure and reveal the surface beyond the extended outer edge of the multi-layer structure; and
depositing an encapsulation layer to seal the extended outer edge of the multi-layer structure.

20. The method of claim 18, wherein depositing the spacer dielectric layer comprises depositing the spacer dielectric layer in a film thickness that is proportionally related to a thickness of the sidewall.

21. The method of claim 18, wherein depositing the spacer dielectric layer further comprises depositing the spacer dielectric layer consisting of a selected dielectric material that is one of: silicon nitride (SiN), silicon dioxide (SiO₂), silicon (Si), silicon oxynitride (SiON), a SiN liner with an oxide spacer, and a SiN liner with an SiON spacer.

22. The semiconductor device of claim 1, wherein the multi-layer structure comprises:
a field oxide layer provided on the surface;
an inter-layer dielectric (ILD) layer provided over the field oxide layer; and
a final passivation layer provided over the ILD layer; and
wherein each of the field oxide layer, the ILD layer, and the final passivation layer is terminated at an inner edge of the sidewall.
